(19) United States
(12) Patent Application Publication
(10) Pub. No.: US 2025/0147413 A1
(43) Pub. Date: May 8, 2025

(54) METHOD FOR PRODUCING STRUCTURE HAVING PHASE-SEPARATED STRUCTURE

(71) Applicant: TOKYO OHKA KOGYO CO., LTD., Kawasaki-shi (JP)

(72) Inventors: Ken MIYAGI, Kawasaki-shi (JP); Takahiro DAZAI, Kawasaki-shi (JP); Junichi TSUCHIYA, Kawasaki-shi (JP); Masaru TAKESHITA, Kawasaki-shi (JP)

(21) Appl. No.: 18/930,500

(22) Filed: Oct. 29, 2024

(30) Foreign Application Priority Data
Nov. 7, 2023 (JP) 2023-189919

(51) Int. Cl. G03F 7/00; G03F 7/16

(52) U.S. Cl. CPC G03F 7/0002; G03F 7/165

(57) ABSTRACT

A method for producing a structure having a phase-separated structure that can improve misalignment of a cylinder structure or line roughness and form alignment marks well. The method includes forming a layer including a block copolymer and having a thickness t on a substrate using a resin composition containing the block copolymer, and separating the layer into a cylinder structure. The thickness t is set such that a relationship between the thickness t and a period L₀ of the block copolymer satisfies a specific formula.

This application claims priority to Japanese Patent Application No. 2023-189919, filed Nov. 7, 2023, the entire content of which is incorporated herein by reference.

### BACKGROUND OF THE INVENTION

### Field of the Invention

The present invention relates to a production method for a structure having a phase-separated structure, a method for improving misalignment of a cylinder structure and alignment mark formation, and a method for improving line roughness and alignment mark formation.

### Related Art

In recent years, following further miniaturization of a large-scale integrated circuit (LSI), a technique for processing a finer structure has been demanded. In response to this demand, a technique has been developed to form finer patterns by utilizing a phase-separated structure formed by directed self-assembly (DSA) of block copolymers in which mutually incompatible blocks are bonded to each other (see, for example, Patent Document 1).

The block copolymers separate (phase-separate) into micro-regions due to repulsion between the mutually incompatible blocks, then are subjected to heat treatment, etc. to form a structure having a regular periodic structure. The periodic structure may be a cylinder (columnar), lamella (plate-like), or sphere (spherical), etc.

To use this phase-separated structure of block copolymers, it is essential that the self-assembled nanostructures formed by micro-phase separation be formed only in specific regions and be arranged in the desired direction. To control the position and orientation of these nanostructures, processes such as graphene epitaxy, which controls phase separation patterns by guiding patterns, and chemical epitaxy, which controls phase separation patterns by differences in the chemical state of the substrate, have been proposed (see, for example, Non-Patent Document 1).
Patent Document 1: Japanese Unexamined Patent Application, Publication No. 2008-36491
Non-Patent Document 1: Proc. SPIE 7637, Alternative Lithographic Technologies II, 76370G (1 Apr. 2010)

### SUMMARY OF THE INVENTION

When forming a line-and-space (LS) pattern using a lamellar structure, it is desirable that line roughness such as line edge roughness (LER) is improved. When forming a contact hole (CH) pattern using a cylinder structure, the cylinder structure is formed at a position corresponding to the hexagonal-most dense structure in a plan view, and it is necessary to prevent the cylinder structure from being formed at the wrong position.

When forming a DSA pattern for device fabrication, alignment (substrate position control) within a lithography process used in conjunction with DSA patterning is necessary. For alignment, alignment marks for position recognition, along with the DSA pattern, must be well formed.

The present invention has been made in view of the above circumstances, with the object of providing a production method for a structure having a phase-separated structure, which can improve misalignment of a cylinder structure or line roughness and can form alignment marks well. Another object of the invention is to provide a method for improving misalignment of a cylinder structure and alignment mark formation, as well as a method for improving line roughness and alignment mark formation.

As a result of extensive studies to solve the above problem, the present invention has been completed based on findings that the above object can be solved if the thickness of the layer including the block copolymer is set such that the relationship between the thickness and the period of the block copolymer satisfies a specific formula. Specifically, the present invention provides the following aspects.

A first aspect of the present invention relates to a production method for a structure having a phase-separated structure, the method including:
a step (a1) of forming a layer including a block copolymer and having a thickness t (nm) on a substrate using a resin composition containing the block copolymer; and
a step (a2) of phase separating the layer into a cylinder structure,
in the step (a1), the thickness t being set such that a relationship between the thickness t and a period L₀ (nm) of the block copolymer satisfies formula (a):

$$( 2 {L}_{0} + ( {3}^{0.5} / 2 ) {L}_{0} \times n ) \times 0.9 \leq t \leq ( 2 {L}_{0} + ( {3}^{0.5} / 2 ) {L}_{0} \times n ) \times 1.1 \qquad ( a )$$

(in formula (a), n is an integer between 0 and 3 inclusive.)

A second aspect of the present invention relates to a method for improving misalignment of a cylinder structure and alignment mark formation, the method including:
a step (a1) of forming a layer including a block copolymer and having a thickness t (nm) on a substrate using a resin composition containing the block copolymer; and
a step (a2) of phase separating the layer into a cylinder structure,
in the step (a1), the thickness t being set such that a relationship between the thickness t and a period L₀ (nm) of the block copolymer satisfies formula (a):

$$( 2 {L}_{0} + ( {3}^{0.5} / 2 ) {L}_{0} \times n ) \times 0.9 \leq t \leq ( 2 {L}_{0} + ( {3}^{0.5} / 2 ) {L}_{0} \times n ) \times 1.1 \qquad ( a )$$

(in formula (a), n is an integer between 0 and 3 inclusive.)

A third aspect of the present invention relates to a production method for a structure having a phase-separated structure, the method including:
a step (b1) of forming a layer including a block copolymer and having a thickness t (nm) on a substrate using a resin composition containing the block copolymer; and
a step (b2) of phase separating the layer into a lamellar structure,
in the step (b1), the thickness t being set such that a relationship between the thickness t and a period L₀ (nm) of the block copolymer satisfies formula (b):

$$( 1.5 {L}_{0} + 0.5 {L}_{0} \times m ) \times 0.95 \leq t \leq ( 1.5 {L}_{0} + 0.5 {L}_{0} \times m ) \times 1.05 \qquad ( b )$$

(in formula (b), m is an integer between 0 and 5 inclusive.)

A fourth aspect of the present invention is a method for improving line roughness and alignment mark formation, the method including:
a step (b1) of forming a layer including a block copolymer and having a thickness t (nm) on a substrate using a resin composition containing the block copolymer; and
a step (b2) of phase separating the layer into a lamellar structure,
in the step (b1), the thickness t being set such that a relationship between the thickness t and a period L₀ (nm) of the block copolymer satisfies formula (b):

$$( 1.5 {L}_{0} + 0.5 {L}_{0} \times m ) \times 0.95 \leq t \leq ( 1.5 {L}_{0} + 0.5 {L}_{0} \times m ) \times 1.05 \qquad ( b )$$

(In formula (b), m is an integer between 0 and 5 inclusive.)

According to the present invention, a production method for a structure having a phase-separated structure that can improve misalignment of a cylinder structure or line roughness and form alignment marks well, can be provided. Further, a method for improving misalignment of a cylinder structure and alignment mark formation, as well as a method for improving line roughness and alignment mark formation, can be provided.

### BRIEF DESCRIPTION OF THE DRAWINGS

FIG. 1 is a diagram illustrating an example of an alignment mark;

FIGS. 2A and 2B are a cross-sectional diagram of a horizontally oriented region of a well-formed alignment mark;

FIG. 3 is a cross-sectional view of a horizontally oriented region of an alignment mark where extra irregularities are formed;

FIG. 4 is a schematic process diagram illustrating an exemplary embodiment of a production method according to a first aspect;

FIG. 5 is a diagram illustrating an exemplary embodiment of an optional process according to the first aspect; and

FIG. 6 is a schematic process diagram illustrating an exemplary embodiment of a production method according to a third aspect.

### DETAILED DESCRIPTION OF THE INVENTION

Although embodiments of the present invention will be described below in detail, the present invention is not limited to the embodiments below in any way and can be implemented with modifications as appropriate within the scope of the object of the present invention.

As used herein, the term “aliphatic” is defined as a concept relative to aromatic and means, for example, a group or a compound having no aromaticity. Unless otherwise specified, the phrase “alkyl group” means a linear- or branched-chain monovalent saturated hydrocarbon group. The same applies to an alkyl group in an alkoxy group. Unless otherwise specified, the phrase “cycloalkyl group” means a monocyclic cyclic saturated hydrocarbon group. Unless otherwise specified, the phrase “alkylene group” means a linear- or branched-chain divalent saturated hydrocarbon group. The phrase “halogenated alkyl group” means a group in which a portion or all of hydrogen atoms in an alkyl group is substituted with a halogen atom. Examples of the halogen atom include a fluorine atom, a chlorine atom, a bromine atom, or an iodine atom. The phrase “fluorinated alkyl group” or “fluorinated alkylene group” means a group in which a portion or all of the hydrogen atoms in an alkyl group or an alkylene group is substituted with a fluorine atom. The phrase “constituent unit” means a monomer unit (monomeric unit) constituting a polymer compound (resin, polymer, or copolymer). The phrase “constituent unit derived from” means a constituent unit derived from the cleavage of an ethylenic double bond or a cyclic ether. The phrase “may have a substituent” includes both a case where a hydrogen atom (—H) is substituted with a monovalent group and a case where a methylene group (—CH₂—) is substituted with a divalent group. The term “exposure” means general irradiation with radiation. Unless otherwise specified, the term “position a (carbon atom at a position a)” means a carbon atom to which a side chain of a block copolymer is bonded. The “carbon atom at a position a” of a methyl methacrylate unit means a carbon atom to which a carbonyl group in methacrylic acid is bonded. The “carbon atom at a position a” of a styrene unit means a carbon atom to which a benzene ring is bonded. Unless otherwise specified, the phrase “number average molecular weight” (Mn) means a number average molecular weight in terms of standard polystyrene measured by size-exclusion chromatography. Unless otherwise specified, the phrase “weight average molecular weight” (Mw) means a weight average molecular weight in terms of standard polystyrene measured by size-exclusion chromatography. When a value of Mn or Mw is followed by a unit (gmol⁻¹), the value represents a molar mass. Herein, an asymmetric carbon may exist depending on the structure represented by a chemical formula, and thus an enantiomer or a diastereomer may exist. In such cases, one formula is used to represent these isomers. Those isomers may be used alone or used as a mixture. As used herein, the phrase “structural period” means a period of a phase structure observed when a structure having a phase-separated structure is formed and refers to a sum of lengths of phases incompatible with each other. In a case where a phase-separated structure forms a cylinder structure perpendicular to a surface of a substrate, the structural period (L₀) is the distance between centers (pitch) of the two adjacent cylinder structures. It is known that a structural period (L₀) is determined by inherent polymerization properties such as the degree of polymerization N and the Flory-Huggins interaction parameter χ. That is, the larger the product of χ and N “χ·N”, the greater the mutual repulsion between the different blocks in the block copolymer. Therefore, in the case of χ·N>10.5 (hereinafter, referred to as “intensity separation limit”), repulsion between different kinds of blocks in the block copolymer is large, leading to a stronger tendency to cause phase separation. Accordingly, at the intensity separation limit, the structural period is approximately N^{2/3}·χ^{1/6} and the relationship expressed in the following formula (cy) is satisfied. That is, the structural period is proportional to the degree of polymerization N, which correlates with the molecular weight and the molecular weight ratio between different blocks.

$${L}_{0} ∝ a \cdot {N}^{2 / 3} \cdot {χ}^{1 / 6} \qquad ( cy )$$

In the formula, L₀ denotes a structural period; a is a parameter indicating a size of a monomer; N denotes a degree of polymerization; and χ is an interaction parameter, in which a higher value means a higher phase separation performance.

Accordingly, the structural period (L₀) can be controlled by adjusting the composition and total molecular weight of a block copolymer.

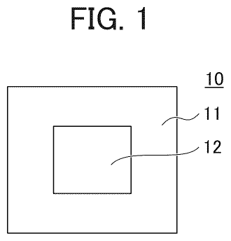

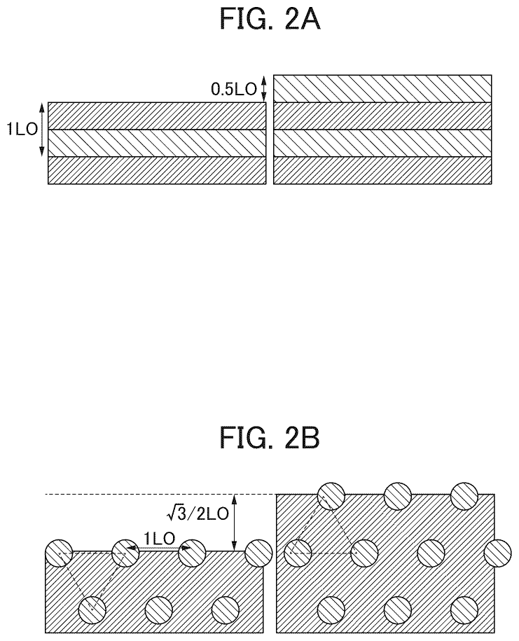

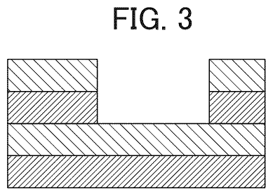

To address the above issue, the inventors found that the thicker a layer containing the block copolymer was made, the more improvement was seen in misalignment of a cylinder structure and line roughness. On the other hand, there were cases where alignment marks could not be formed well due to the thickness of the layer. Alignment marks in DSA patterning are generally formed by using the orientation of the block copolymers and combining horizontally oriented regions and vertically oriented regions. For example, in FIG. 1, an alignment mark 10 is formed in which a rectangular horizontally oriented region 11 surrounds a rectangular vertically oriented region 12 in the plan view. In an alignment mark that was not formed well, extra irregularities such as circular irregularities were formed in the horizontally oriented region. Note that, the term “horizontally orientated” as used herein means an orientation state in which a horizontal interface is formed relative to the surface of the substrate in a phase-separated state. Usually, the direction perpendicular to the direction in which gravity acts is called the horizontal direction. However, the phrase “horizontally orientated” as used herein may also mean that the interface between phases formed by phase separation need not be a horizontal plane. The phrase “vertically oriented” as used herein means an orientation state in which an interface perpendicular to the surface of the substrate is formed in a phase-separated state. The inventors found that, if the thickness of the layer is set such that the relationship with L₀ satisfies a specific formula, no extra unevenness is formed in the horizontally oriented region and that alignment marks can be formed well. The reasons for this can be inferred as follows. When a lamellar structure is horizontally oriented, the phase-separated phases alternate at a cycle of around 0.5L₀ in the vertical direction, as shown in FIG. 2A. Therefore, if the thickness is set near the 0.5L₀ cycle, no extra unevenness is formed. On the other hand, if the thickness is set outside the vicinity of the above cycle, as shown in FIG. 3, a region where the phase-separated structure does not exist for one cycle is generated, and extra unevenness is formed. When a cylinder structure is horizontally oriented, the cylinder structure aligns vertically at a cycle of around (3^{0.5}/2) L₀, as shown in FIG. 2B. Therefore, if the thickness is set near the cycle of (3^{0.5}/2) L₀, no extra unevenness is formed. On the other hand, if the thickness is set outside the vicinity of the above cycle, extra irregularities are formed, as in the lamellar structure.

### First Aspect: Production Method for Structure Having Phase-separated Structure (Cylinder Structure)

A production method according to a first aspect includes a step (a1) of forming a layer including a block copolymer and having a thickness t (nm) on a substrate using a resin composition containing the block copolymer, and a step (a2) of phase separating the layer into a cylinder structure. In the step (a1), the thickness t is set such that the relationship between the thickness t and the block copolymer period L₀ (nm) satisfies the following formula (a).

$$( 2 {L}_{0} + ( {3}^{0.5} / 2 ) {L}_{0} \times n ) \times 0.9 \leq t \leq ( 2 {L}_{0} + ( {3}^{0.5} / 2 ) {L}_{0} \times n ) \times 1.1 \qquad ( a )$$

(In Formula (a), n is an integer between 0 and 3 inclusive.)

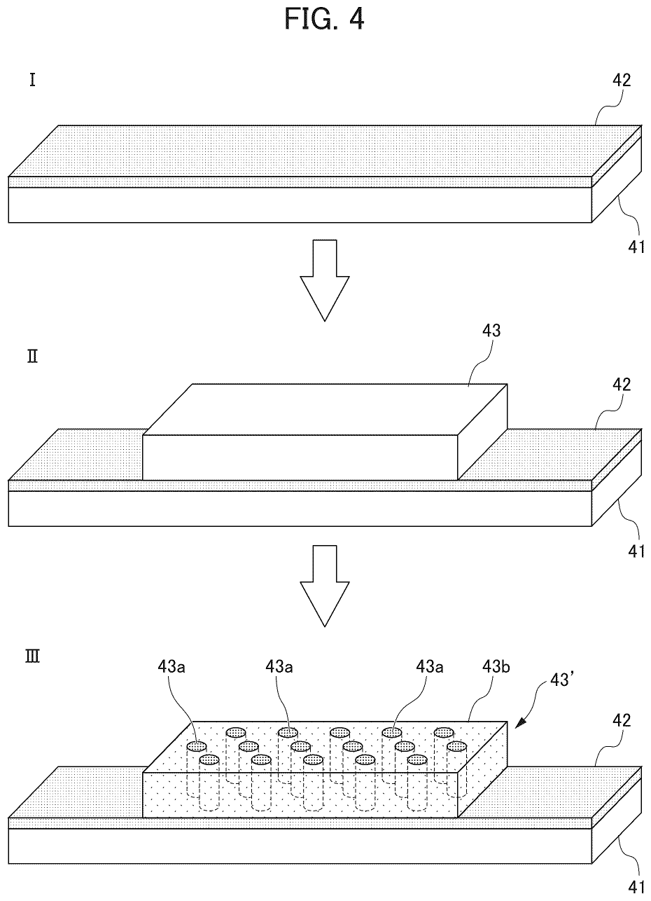

Now, the production method for a structure having a phase-separated structure will be described in detail with reference to FIG. 4. However, the production method for a structure having a phase-separated structure according to the first aspect is not limited to the specific embodiment illustrated in FIG. 4.

FIG. 4 illustrates an embodiment of a production method for a structure having a phase-separated structure. In the embodiment illustrated in FIG. 4, a substrate 41 is first coated with a primer, and a layer 42 consisting of a neutralized film (FIG. 4(I)) is formed. Although not shown in FIG. 4, a film having affinity with one of the blocks constituting the block copolymer is formed in the region to be horizontally oriented in the alignment mark, and the neutralized film is formed in the region to be vertically oriented. Next, a layer (BCP layer) 43 including a block copolymer and having the thickness t (nm) is formed by applying a resin composition for forming a phase-separated structure on a layer 42 consisting of a neutralized film and on the region where alignment marks are to be formed (FIG. 4 (II); step (a1) complete). Next, the BCP layer 43 is annealed by heating to separate the BCP layer 43 into a phase 43a and a phase 43b (FIG. 4 (III); step (a2)). According to the production method of this embodiment, that is, the production method including the step (a1) and the step (a2), a structure 43′ having a phase-separated structure is produced on a substrate 41, on which a layer 42 consisting of a neutralized film is formed. In addition, alignment marks with horizontally oriented regions and vertically oriented regions are formed.

### Step (a1)

In the step (a1), the resin composition for forming the phase-separated structure is applied on a substrate 41 to form a BCP layer 43 having the thickness t (nm).

The type of a substrate 41 is not limited as long as the resin composition can be applied on its surface. Examples thereof include a substrate consisting of an inorganic material such as a silicon, a metal (e.g., copper, chromium, iron, or aluminum), glass, titanium oxide, silica, or mica; a substrate consisting of an oxide such as SiO₂; a substrate consisting of a nitride such as SiN; a substrate consisting of an oxynitride such as SiON; or a substrate consisting of an organic material such as acryl resin, polystyrene, cellulose, cellulose acetate, or a phenolic resin. Among them, a silicon substrate (Si substrate) or a metal substrate is suitable, an Si substrate or a copper substrate (Cu substrate) is more suitable, and a Si substrate is particularly suitable. The size and shape of the substrate 41 are not limited. The substrate 41 does not necessarily need to have a smooth surface, and substrates of various shapes can be selected as appropriate. For example, a substrate having a curved surface, a flat plate having an uneven surface, or a flaky substrate may be used.

An inorganic and/or organic film may be provided on a surface of the substrate 41. An example of the inorganic film is an inorganic antireflection film (inorganic BARC). An example of the organic film is an organic antireflection film (organic BARC). The inorganic films can be formed, for example, by applying an inorganic antireflection film composition such as a silicon-based material on a support and baking the resultant. The organic films can be formed, for example, by applying the organic film material, in which a resin component constituting the organic film is dissolved in an organic solvent, on a substrate using a spinner, etc., and baking the resultant under heating conditions of preferably 200° C. or higher and 300° C. or lower for preferably 30 seconds or more and 300 seconds or less and more preferably for 60 seconds or more and 180 seconds or less. The material for forming organic films does not necessarily require sensitivity to light or electron beams, such as resist films, and may or may not have such sensitivity. Specifically, a resist or a resin generally used for producing semiconductor elements or liquid crystal display elements may be used. Furthermore, the material for forming the organic film is preferably a material capable of forming an organic film that can be subjected to etching, particularly dry-etching so that a pattern may be formed on the organic film by transferring the pattern of the phase-separated structure on the organic film. Among them, a material capable of forming an organic film that can be subjected to etching such as oxygen plasma etching is preferable. Such a material for forming an organic film may be a material conventionally used for forming an organic film such as organic BARC. Examples thereof include the ARC series manufactured by Nissan Chemical Corporation, the AR series manufactured by Rohm and Haas Japan Ltd., or the SWK series manufactured by TOKYO OHKA KOGYO CO., LTD.

In the embodiment illustrated in FIG. 4, an undercoat agent is applied to the substrate 41, and then the layer 42 consisting of a neutralized film is formed on the substrate 41. Thus, it is preferable to provide the layer 42 consisting of a neutralized film on the substrate 41. This configuration allows a hydrophilic-hydrophobic balance to be achieved between the substrate 41 surface and the layer containing the block copolymer (BCP layer) 43. In the region to be horizontally oriented in the alignment mark, it is preferable that a layer consisting of a film having affinity with any block of the block copolymer is formed on the substrate 41, and in the region to be vertically oriented, it is preferable that a layer consisting of a neutralized film is formed on the substrate 41. This allows each region to be oriented as intended.

A resin composition can be used as the undercoat agent. The resin composition for the undercoat agent can be appropriately selected from conventionally known resin compositions to be used for forming a thin film depending on a kind of a block constituting a block copolymer. The resin composition for the undercoat agent may be, for example, a thermopolymerizable resin composition or may be a photosensitive resin composition such as a positive-type resist composition or a negative-type resist composition. Furthermore, a non-polymerizable film formed by applying a compound serving as a surface treating agent may also be used as a neutralized film. For example, a siloxane-based organic monomolecular film formed by applying phenethyltrichlorosilane, octadecyltrichlorosilane, hexamethyldisilazane, etc., as a surface-treating agent can also be suitably used as the neutralized film.

As the resin composition for the undercoat agent, for example, the use of a composition containing a resin having both styrene and methyl methacrylate as a constituent unit, or a compound or a composition including both a moiety having a high affinity with styrene such as an aromatic ring and a moiety having a high affinity with methyl methacrylate (e.g., a highly polar functional group), is preferable. Examples of the resin having both styrene and methyl methacrylate as a constituent unit include a random copolymer of styrene and methyl methacrylate, an alternating polymer of styrene and methyl methacrylate (polymer in which each monomer is alternately copolymerized), or the like. Furthermore, examples of the composition including both a moiety having a high affinity with styrene and a moiety having a high affinity with methyl methacrylate include a composition containing a resin obtained by polymerizing at least a monomer having an aromatic ring and a monomer having a high polarity functional group. Examples of the monomer having an aromatic ring include: a monomer having an aryl group in which one hydrogen atom is removed from an aromatic hydrocarbon ring such as a phenyl group, a biphenyl group, a fluorenyl group, a naphthyl group, an anthryl group, or a phenanthryl group, or a heteroaryl group in which a portion of carbon atoms constituting a ring on any of the above-mentioned groups is substituted with a heteroatom such as an oxygen atom, a sulfur atom or a nitrogen atom. Furthermore, examples of the monomer having a highly polar functional group include: a monomer having a trimethoxysilyl group, a trichlorosilyl group, an epoxy group, a glycidyl group, a carboxy group, a hydroxy group, a cyano group, or a hydroxyalkyl group in which a portion of hydrogen atoms in an alkyl group is substituted with a hydroxy group. Other examples of the compound including both a moiety having a high affinity with styrene and a moiety having a high affinity with methyl methacrylate include: a compound including both an aryl group and a highly polar functional group such as phenethyltrichlorosilane, or a compound including both an alkyl group and a highly polar functional group such as an alkylsilane compound.

The resin composition for the undercoat agent can be produced by dissolving the above-mentioned resin in a solvent. Such a solvent may be any solvent as long as it can dissolve each component to be used and form a homogeneous solution. For example, the same organic solvent component as one exemplified in the above-mentioned description for the resin composition for forming a phase-separated structure may be used.

A method for forming the layer 42 consisting of a neutralized film by applying the undercoat agent on the substrate 41 is not particularly limited, and any conventionally known method may be used to form the layer 42 consisting of a neutralized film. For example, the undercoat agent may be applied to the substrate 41 by a conventionally known method such as spin coating or by using a spinner to form a coating film, which is then dried to form the layer 42 consisting of a neutralized film. A method for drying the coating film is not limited as long as a solvent included in the undercoat agent can be volatilized; for example, baking may be used. In this case, a baking temperature is preferably 80° C. or higher and 300° C. or lower, more preferably 180° C. or higher and 270° C. or lower, and further preferably 220° C. or higher and 250° C. or lower. A baking time is preferably 30 seconds or more and 500 seconds or less and more preferably 60 seconds or more and 400 seconds or less. A thickness of the layer 42 consisting of a neutralized film after drying the coating film is preferably about 10 nm or more and 100 nm or less and more preferably about 40 nm or more and 90 nm or less.

The surface of the substrate 41 may be pre-cleaned before forming the layer 42 consisting of a neutralized film on the substrate 41. Cleaning the surface of the substrate 41 improves the application of the undercoat agent. A conventionally known cleaning treatment method can be used, and examples thereof include an oxygen plasma treatment, an ozone oxidation treatment, an acid alkali treatment, a chemical modification treatment, or the like.

After the layer 42 consisting of a neutralized film is formed, the layer 42 consisting of a neutralized film may be rinsed with a rinsing liquid such as a solvent, as necessary. Since the rinse removes uncrosslinked portions and the like of the layer 42 consisting of a neutralized film, affinity with at least one block constituting a block copolymer is improved, and thus, a phase-separated structure oriented in a direction perpendicular to a surface of the substrate 41 is likely to be formed. The rinse solution can be any liquid that can dissolve the uncrosslinked portions. Solvents such as propylene glycol monomethyl ether acetate (PGMEA), propylene glycol monomethyl ether (PGME), ethyl lactate (EL), or commercially available thinner solutions can be used. After the cleaning, post-baking may be performed to volatilize the rinse solution. A temperature condition during the post-baking is preferably 80° C. or higher and 300° C. or lower, more preferably 100° C. or higher and 270° C. or lower, and further preferably 120° C. or higher and 250° C. or lower. The baking time is preferably 30 seconds or more and 500 seconds or less and more preferably 60 seconds or more and 240 seconds or less. The thickness of the layer 42 consisting of a neutralized film after the post-baking is preferably about 1 nm or more and 10 nm or less and more preferably about 2 nm or more and 7 nm or less.

Next, the layer (BCP layer) 43 containing block copolymers and having the thickness t (nm) is formed by applying the resin composition for forming a phase-separated structure (described below) on the layer 42 consisting of a neutralized film and on the region where alignment marks are to be formed. The method of forming the BCP layer 43 is not particularly limited, and includes, for example, a method in which the resin composition for forming a phase-separated structure is applied on the layer 42 consisting of a neutralized film and on the region where alignment marks are to be formed by a conventionally known method such as spin coating or use of a spinner to form a coated film and then the coated film is dried. The method of drying the coating film of the resin composition for forming a phase-separating structure is only required to volatilize the organic solvent component contained in the resin composition for forming a phase-separating structure and, for example, a baking method may be used.

In this aspect, the thickness t of the BCP layer 43 is set such that the relationship between the thickness t and the block copolymer period L₀ (nm) satisfies the following equation (a).

$$( 2 {L}_{0} + ( {3}^{0.5} / 2 ) {L}_{0} \times n ) \times 0.9 \leq t \leq ( 2 {L}_{0} + ( {3}^{0.5} / 2 ) {L}_{0} \times n ) \times 1.1 \qquad ( a )$$

(In formula (a), n is an integer between 0 and 3 inclusive.)

Setting the thickness to a larger thickness (2L₀×0.9 or more) improves misalignment of the cylinder structure, and setting the thickness near the (3^{0.5}/2) L₀ cycle results in good alignment mark formation.

The thickness t of the BCP layer 43 means the thickness of the layer containing the block copolymer after the coating film of the resin composition for forming a phase-separated structure is dried.

n is preferably an integer between 1 and 3, as it makes improving misalignment of the cylinder structure easier.

The thickness t of the BCP layer 43 is not limited as long as the above formula (a) is satisfied and, for example, is 40 to 180 nm or 60 to 160 nm.

The method of adjusting the thickness of the BCP layer 43 is not particularly limited and includes, for example, a method of adjusting the concentration of the block copolymer in the resin composition for forming a phase-separated structure, or adjusting the rotation speed when using the spin coating method.

### Step (a2)

In the step (a2), the BCP layer 43 formed on the substrate 41 is phase-separated to form a cylinder structure. For example, the substrate 41 is annealed by heating to produce a structure 43′ having a phase-separated structure separated into the phase 3a and the phase 3b. In a subsequent step, the phase is selectively removed to expose at least a portion of the surface of the substrate 41. Horizontally oriented phase-separated structures are obtained in the horizontally oriented regions of the alignment marks, and vertically oriented phase-separated structures are obtained in the vertically oriented regions. The temperature condition during the annealing treatment is preferably the glass transition temperature of the block copolymer used or higher, and lower than the thermal decomposition temperature of the block copolymer used. For example, in the case of a polystyrene-polymethyl methacrylate (PS-PMMA) block copolymer (weight average molecular weight: 5000 or more and 100000 or less), the temperature condition is preferably 180° C. or higher and 270° C. or lower, more preferably 200° C. or higher and 270° C. or lower, and further preferably 220° C. or higher and 260° C. or lower. The heating time is preferably 1 minute or more and 1 hour or less, more preferably 2 minutes or more and 45 minutes or less, and further preferably 5 minutes or more and 30 minutes or less. The annealing treatment is preferably performed in a less reactive gas such as nitrogen.

### Optional Step

The production method for a structure having a phase-separated structure is not limited to the embodiment described above and may include a step other than the step (a1) and the step (a2) (an optional step).

Examples of the optional step include a step of selectively removing a phase consisting of at least one of the blocks constituting the block copolymer of the BCP layer 43 (hereinafter referred to as “Step (a3)”), and a guide pattern formation step.

### Step (a3)

In the step (a3), a phase consisting of at least one of blocks constituting the block copolymer is selectively removed from the BCP layer 43, which is formed on the layer 42 consisting of a neutralized film. This results in formation of a fine pattern (polymer nanostructure).

Examples of the method for selectively removing the phase consisting of the block include a method for subjecting the BCP layer to an oxygen plasma treatment or a method for subjecting the BCP layer to a hydrogen plasma treatment. In the following description, of the blocks constituting the block copolymer, blocks that are not selectively removed are referred to as “P_{A} blocks” and blocks that are selectively removed are referred to as “P_{B} blocks”. For example, when a layer including a PS-PMMA block copolymer is phase-separated and then the BCP layer is subjected to an oxygen plasma treatment or a hydrogen plasma treatment, the phase consisting of PMMA is selectively removed. In this case, the PS portion is the P_{A} block and the PMMA portion is the P_{B} block.

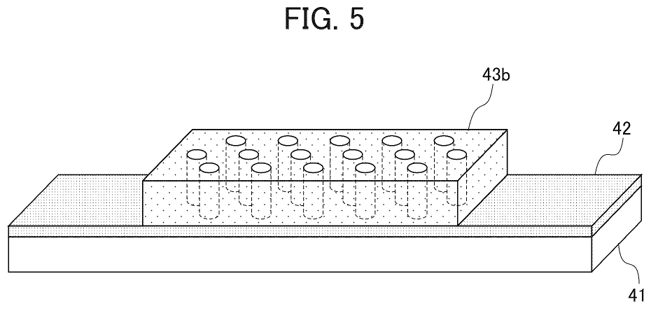

FIG. 5 shows an exemplary embodiment of the step (a3). In the embodiment illustrated in FIG. 5, the phase 43a is selectively removed by oxygen plasma treatment from the structure 43′ produced on the substrate 41 in the step (a2) to form a pattern (polymer nanostructure) consisting of separated phases 43b. In this case, the phase 43b is the phase consisting of P_{A} blocks and phase 43a is the phase consisting of P_{B} blocks.

The substrate 41 with the pattern formed by phase separation of the BCP layer 43 as described above can be used as is, or the shape of the pattern (polymer nanostructure) on the substrate 41 can be changed by further heating. The temperature condition during the heating is preferably a glass transition temperature of the block copolymer used or higher, and lower than the thermal decomposition temperature of the block copolymer used. The heating is preferably performed in a less reactive gas such as nitrogen.

### Guide Pattern Formation Step

The production method for a structure having a phase-separated structure may also include a step of forming a guide pattern in the layer consisting of a neutralized film (guide pattern formation step). This allows for control of the array structure of the phase-separated structure. For example, even for block copolymers that form a random fingerprint-like phase-separated structure when no guide pattern is provided, a groove structure of a resist film can be provided on the layer consisting of a neutralized film to obtain a phase-separated structure oriented along the groove. The affinity of the surface of the guide pattern to any of the blocks comprising the above block copolymer facilitates the formation of a phase-separated structure oriented perpendicular to the substrate surface.

The guide pattern can be formed by, for example, using a resist composition. For the resist composition forming the guide pattern, a resist composition having affinity with any of the blocks constituting the above block copolymers can be selected from among resist compositions generally used for forming resist patterns or their modifications. The resist composition may be either a positive-type resist composition from which a positive-type pattern is formed, that is, an exposed area of a resist film is dissolved and removed or a negative-type resist composition from which a negative-type pattern is formed, that is, an unexposed area of a resist film is dissolved and removed, but a negative-type resist composition is preferable. The negative-type resist composition is preferably a resist composition that contains, for example, an acid generating agent and a base material component having a solubility in an organic solvent-containing developing solution that decreases under action of an acid, the base material component containing a resin component that has a constituent unit degraded under action of an acid to have an increased polarity. After the resin composition for forming a phase-separated structure is poured onto the layer consisting of a neutralized film including the guide pattern, an annealing process is performed to cause phase separation. Therefore, a resist composition capable of forming a resist film while having excellent solvent resistance and heat resistance is preferable as the resist composition for forming the guide pattern.

### Resin Composition for Forming Phase-separated Structure

The resin composition for forming a phase-separated structure used in the production method according to the first aspect contains a block copolymer.

### Block Copolymer

A block copolymer is a polymer consisting of multiple types of blocks (sub-constituents of the same type of constituent units repeatedly bonded). There may be two, three or more types of blocks comprising the block copolymer. The multiple types of blocks that make up the block copolymer are not limited to any particular combination by which phase separation occurs. However, it is preferred that the blocks be a combination of blocks that are incompatible with each other. It is preferred that a phase consisting of at least one of the multiple types of blocks comprising the block copolymer is a combination that can be more easily and selectively removed than the phase consisting of other types of blocks. Examples of a combination that is easily selectively removable is a block copolymer with one or more blocks bonded together with an etching selectivity ratio greater than 1.

Examples of the block copolymer include a block copolymer in which a block of a component unit having an aromatic group is bonded to a block of a component unit derived from an (α-substituted) acrylic ester; a block copolymer in which a block of a component unit having an aromatic group is bonded to a block of a component unit derived from an (α-substituted) acrylic acid; a block copolymer in which a block of a component unit having an aromatic group is bonded to a block of a component unit derived from a siloxane or a derivative thereof; a block copolymer in which a block of a component unit derived from an alkylene oxide is bonded to a block of a component unit derived from an (α-substituted) acrylic acid ester; a block copolymer in which a block of a component unit derived from an alkylene oxide is bonded to a block of a component unit derived from an (α-substituted) acrylic acid ester; a block copolymer in which a block of a component unit having a silsesquioxane structure is bonded to a block of a component unit derived from an (α-substituted) acrylic acid ester; a block copolymer in which a block of a component unit having a silsesquioxane structure is bonded to a block of a component unit derived from an (α-substituted) acrylic acid; and a block copolymer in which a block of a component unit having a silsesquioxane structure is bonded to a block of a component unit derived from siloxane or a derivative thereof.

Examples of the component unit having an aromatic group include a component unit having a phenyl group, a naphthyl group, or other aromatic groups. Among them, a component unit derived from styrene or its derivatives is preferred. Examples of styrene or its derivatives include styrene, α-methylstyrene, 2-methylstyrene, 3-methylstyrene, 4-methylstyrene, 2-ethylstyrene, 3-ethylstyrene, 4-ethylstyrene, 4-tert-butylstyrene, 4-n-ocytlstyrene, 2,4,6-trimethylstyrene, 4-methoxystyrene, 4-tert-butoxystyrene, 4-hydroxystyrene, 4-nitrostyrene, 3-nitrostyrene, 4-chlorostyrene, 4-fluorostyrene, 4-acetoxyvinylstyrene, 4-vinylbenzylchloride, 1-vinylnaphthalene, 4-vinylbiphenyl, 1-vinyl-2-pyrrolidone, 9-vinylanthracene, and vinylpyridine.

(α-substituted) acrylic acid means one or both of an acrylic acid or a compound in which the hydrogen atom attached to the carbon atom at a position a in acrylic acid is substituted with a substituent. An example of the substituent is an alkyl group with 1 or more and 5 or less carbon atoms. Examples of an (α-substituted) acrylic acid include acrylic acid and methacrylic acid.

(α-substituted) acrylic ester means one or both of an acrylic ester or a compound in which the hydrogen atom attached to the carbon atom at a position a in the acrylic ester is substituted with a substituent. An example of the substituent is an alkyl group with 1 or more and 5 or less carbon atoms. Examples of the (α-substituted) acrylic ester include acrylic esters such as methyl acrylate, ethyl acrylate, propyl acrylate, n-butyl acrylate, tert-butyl acrylate, cyclohexyl acrylate, octyl acrylate, nonyl acrylate, hydroxyethyl acrylate, hydroxypropyl acrylate, benzyl acrylate, anthracene acrylate, glycidyl acrylate, 3,4-epoxycyclohexyl methane acrylate, propyl trimethoxysilane acrylate, and 2-hydroxy-3-(2,2,2-trifluoroethylsulfanyl) propyl acrylate; and methacrylic esters such as methyl methacrylate, ethyl methacrylate, propyl methacrylate, n-butyl methacrylate, tert-butyl methacrylate, cyclohexyl methacrylate, octyl methacrylate, nonyl methacrylate, hydroxyethyl methacrylate, hydroxypropyl methacrylate, benzyl methacrylate anthracene methacrylate, glycidyl methacrylate, 3,4-epoxycyclohexylmethane methacrylate, propyl trimethoxysilane methacrylate, and 2-hydroxy-3-(2,2,2-trifluoroethylsulfanyl) propyl methacrylate. Among these, methyl acrylate, ethyl acrylate, tert-butyl acrylate, methyl methacrylate, ethyl methacrylate, and t-butyl methacrylate are preferred.

Examples of the siloxane or derivatives thereof include dimethylsiloxane, diethylsiloxane, diphenylsiloxane, and methylphenylsiloxane. Examples of the alkylene oxide include ethylene oxide, propylene oxide, isopropylene oxide, and butylene oxide. As the component unit having a silsesquioxane structure, a component unit having a cage-shaped silsesquioxane structure is preferred. An example of a monomer that provides the component unit having a cage-shaped silsesquioxane structure is a compound having a cage-shaped silsesquioxane structure and a polymerizable group.

Among them, as the block copolymer, a block copolymer including a block of component units having an aromatic group and a block of component units derived from (α-substituted) acrylic acid or (α-substituted) acrylic ester are preferred.

To obtain a cylinder-like phase-separated structure oriented perpendicularly to the substrate surface, the mass ratio of the component units having an aromatic group and the component units derived from an (α-substituted) acrylic acid or an (α-substituted) acrylic ester is preferably between 60:40 and 90:10 inclusive, more preferably between 60:40 and 80:20 inclusive. In the third aspect to be described below, to obtain a lamellar phase-separated structure oriented perpendicularly to the substrate surface, the mass ratio of the component unit having an aromatic group and the component unit derived from an (α-substituted) acrylic acid or an (α-substituted) acrylic ester is preferably between 35:65 and 60:40 inclusive, more preferably between 40:60 and 60:40 inclusive.

Examples of the block copolymer include, specifically, a block copolymer having a block of component units derived from styrene and a block of component units derived from acrylic acid, a block copolymer having a block of component units derived from styrene and a block of component units derived from methyl acrylate, a block copolymer having a block of component units derived from styrene and a block of component units derived from ethyl acrylate, a block copolymer having a block of component units derived from styrene and a block of component units derived from t-butyl acrylate, a block copolymer having a block of component units derived from styrene and a block of component units derived from methacrylic acid, a block copolymer having a block of component units derived from styrene and a block of component units derived from methyl methacrylate, a block copolymer having a block of component units derived from styrene and a block of component units derived from ethyl methacrylate, a block copolymer having a block of component units derived from styrene and a block of component units derived from t-butyl methacrylate, a block copolymer having a block of component units having a caged silsesquioxane (POSS) structure and a block of component units derived from acrylic acid, and a block copolymer having a block of component units having a caged silsesquioxane (POSS) structure and a block of component units derived from methyl acrylate. In this embodiment, it is particularly preferable to use a block copolymer (PS-PMMA block copolymer) having blocks of component units derived from styrene (PS) and blocks of component units derived from methyl methacrylate (PMMA).

The block copolymer period L₀ (nm) is preferably between 20 and 50 nm inclusive, more preferably between 25 and 45 nm inclusive.

The number-average molecular weight (Mn) (based on polystyrene conversion by gel permeation chromatography) of the block copolymer is preferably between 20000 and 200000 inclusive, more preferably between 30000 and 150000 inclusive, and further preferably between 40000 and 100000 inclusive.

The degree of dispersion (Mw/Mn) of the block copolymer is preferably between 1.0 and 3.0 inclusive, more preferably between 1.0 and 1.5 inclusive, and further preferably between 1.0 and 1.3 inclusive. Note that “Mw” refers to the mass average molecular weight.

In the resin composition for forming a phase-separated structure, one or more types of the block copolymers may be used alone or in combination. In addition to the block copolymer, the same polymer that makes up one of the blocks may be added. The content of the block copolymer in the resin composition for forming a phase-separated structure may be adjusted according to the thickness of the layer containing the block copolymer to be formed.

### Organic Solvent Component

The resin composition for forming a phase-separated structure preferably contains an organic solvent. Any organic solvent may be used as an organic solvent as long as it can dissolve each component to be used and form a homogeneous solution. Conventionally, any organic solvent selected from known organic solvents as a solvent for a composition including a resin as a main component may be used.

Examples of the organic solvent component include a lactone such as γ-butyrolactone; a ketone such as acetone, methyl ethyl ketone, cyclohexanone, methyl-n-pentyl ketone, methyl isopentyl ketone, or 2-heptanone; a polyhydric alcohol such as ethylene glycol, diethylene glycol, propylene glycol, or dipropylene glycol; a polyhydric alcohol monoacetate such as ethylene glycol monoacetate, diethylene glycol monoacetate, propylene glycol monoacetate, or dipropylene glycol monoacetate; a derivative of the polyhydric alcohol such as a polyhydric alcohol or a polyhydric alcohol monoacetate such as monomethyl ether, monoethyl ether, monopropyl ether, or monobutyl ether, or a monophenyl ether of the polyhydric alcohol or the compound having an ester bond [among them, propylene glycol monomethyl ether acetate (PGMEA) or propylene glycol monomethyl ether (PGME) is preferred]; a cyclic ether such as dioxane, or an ester other than a polyhydric alcohol monoacetate and a derivative of the polyhydric alcohols described above, ethyl lactate (EL), methyl acetate, ethyl acetate, butyl acetate, methyl pyruvate, ethyl pyruvate, methyl methoxy propionate, or ethyl ethoxy propionate; an aromatic organic solvent such as anisole, ethyl benzyl ether, cresyl methyl ether, diphenyl ether, dibenzyl ether, phenetole, butyl phenyl ether, ethyl benzene, diethyl benzene, pentyl benzene, isopropyl benzene, toluene, xylene, cymene, or mesitylene. The organic solvent component may be used alone, or two or more may be used as a mixed solvent. Among them, propylene glycol monomethyl ether acetate (PGMEA), propylene glycol monomethyl ether (PGME), cyclohexanone, or ethyl lactate (EL) is preferred.

The organic solvent component in the resin composition for forming a phase-separated structure is not particularly limited. The organic solvent component is determined appropriately according to the coating film thickness such that the resin composition for forming a phase-separated structure has a concentration with which the composition can be applied. The organic solvent component is generally used such that the solid concentration of the resin composition for forming a phase-separated structure is in a range of between 0.2 to 70% by mass inclusive, preferably between 0.2 to 50% by mass inclusive.

### Optional Component

The resin composition for forming a phase-separated structure may contain an optional component other than the block copolymers and the organic solvent components described above. Examples of the optional component include another resin, a surfactant, a dissolution inhibiting agent, a plasticizing agent, a stabilizing agent, a coloring agent, an anti-halation agent, a dye, a sensitizing agent, a base proliferating agent, or a basic compound.

Second Aspect: Method for Improving Misalignment of Cylinder Structure and Alignment Mark Formation

The method according to a second aspect includes a step (a1) of forming a layer containing the block copolymer and having the thickness t (nm) on the substrate using a resin composition containing the block copolymer, and a step (a2) of phase separating the layer into a cylinder structure. In the step (a1), the thickness t is set such that the relationship between the thickness t and the block copolymer period L₀ (nm) satisfies the following formula (a).

$$( 2 {L}_{0} + ( {3}^{0.5} / 2 ) {L}_{0} \times n ) \times 0.9 \leq t \leq ( 2 {L}_{0} + ( {3}^{0.5} / 2 ) {L}_{0} \times n ) \times 1.1 \qquad ( a )$$

(In Formula (a), n is an integer between 0 and 3 inclusive.)

The details of this aspect are the same as those of the production method according to the first aspect.

Third Aspect: Production Method for Structure Having Phase-separated Structure (Lamellar structure)

The production method according to a third aspect includes a step (b1) of forming a layer containing the block copolymer and having the thickness t (nm) on the substrate using a resin composition containing the block copolymer, and a step (b2) of phase separating the layer into a lamellar structure. In the step (b1), the thickness t is set such that the relationship between the thickness t and the block copolymer period L₀ (nm) satisfies the following formula (b).

$$( 1.5 {L}_{0} + 0.5 {L}_{0} \times m ) \times 0.95 \leq t \leq ( 1.5 {L}_{0} + 0.5 {L}_{0} \times m ) \times 1.05 \qquad ( b )$$

(In Formula (b), m is an integer between 0 and 5 inclusive.)

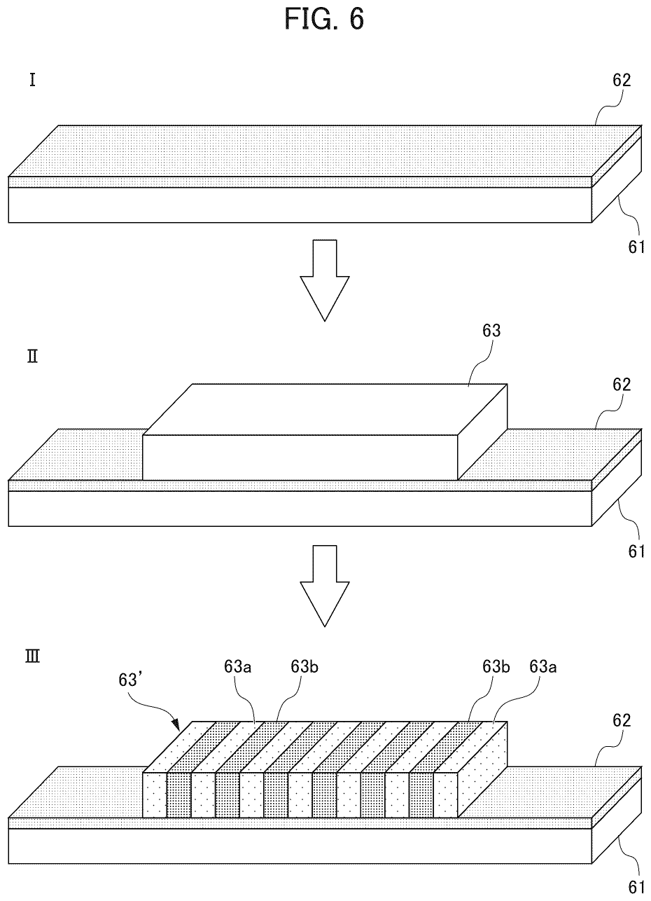

Now, the production method for a structure having a phase-separated structure will be described in detail with reference to FIG. 6. However, the production method for a structure having a phase-separated structure according to the third aspect is not limited to the specific embodiment illustrated in FIG. 6.

FIG. 6 shows an exemplary embodiment of a production method for a structure having a phase-separated structure. In the embodiment illustrated in FIG. 6, the substrate 61 is first coated with an undercoat agent to form the layer 62 consisting of a neutralized film (FIG. 6(I)). Although not illustrated in FIG. 6, a film having affinity with one of the blocks constituting the block copolymer is formed in the region to be horizontally oriented in the alignment mark, and the neutralized film is formed in the region to be vertically oriented. Next, the layer (BCP layer) 63 containing the block copolymer and having the thickness t (nm) is formed by applying the resin composition for forming a phase-separated structure on the layer 62 consisting of a neutralized film and on the region where the alignment marks are to be formed (FIG. 6 (II); step (b1) complete). Next, the BCP layer 63 is annealed by heating to separate the BCP layer 63 into the phase 63a and a phase 63b (FIG. 6 (III); step (b2)). According to the production method of this embodiment, that is, the production method including the step (b1) and the step (b2), the structure 63′ having a phase-separated structure is produced on the substrate 61 including the layer 62 consisting of a neutralized film. In addition, alignment marks with horizontally oriented regions and vertically oriented regions are formed.

In this aspect, the thickness t of the BCP layer 63 is set such that the relationship between the thickness t and the block copolymer period L₀ (nm) satisfies the following formula (b).

$$( 1.5 {L}_{0} + 0.5 {L}_{0} \times m ) \times 0.95 \leq t \leq ( 1.5 {L}_{0} + 0.5 {L}_{0} \times m ) \times 1.05 \qquad ( b )$$

(In Formula (b), m is an integer between 0 and 5 inclusive.)

Setting the thickness to a larger thickness (1.5L₀×0.95 or thicker) improves line roughness, and setting the thickness near the 0.5L₀ cycle results in good alignment mark formation.

m is preferably an integer between 1 and 5, as it makes improving line roughness easier.

The thickness t of the BCP layer 63 is not limited as long as the above formula (b) is satisfied and may be, for example, between 30 and 150 nm inclusive or between 40 and 120 nm inclusive.

Other details of this aspect are the same as those of the production method according to the first aspect.

### Fourth Aspect: Method for Improving Line Roughness and Alignment Mark Formation

A method according to a fourth aspect includes a step (b1) of forming a layer containing the block copolymer and having the thickness t (nm) on the substrate using a resin composition containing the block copolymer, and a step (b2) of phase separating the layer into a lamellar structure. In the step (b1), the thickness t is set such that the relationship between the thickness t and the block copolymer period L₀ (nm) satisfies the following formula (b).

$$( 1.5 {L}_{0} + 0.5 {L}_{0} \times m ) \times 0.95 \leq t \leq ( 1.5 {L}_{0} + 0.5 {L}_{0} \times m ) \times 1.05 \qquad ( b )$$

(In Formula (b), m is an integer between 0 and 5 inclusive.)

The details of this aspect are the same as those of the production method according to the third aspect.

### EXAMPLES

The present invention will now be described in more detail based on examples, but the invention is not limited to these examples.

The block copolymers used in the examples and comparative examples will now be described.

BCP-A: Block copolymer consisting of blocks (PS) consisting of polystyrene and blocks (PMMA) consisting of poly(methyl methacrylate) (Mn: about 56,000, Mw/Mn: 1.02, composition ratio of PS/PMMA (mol %): 50/50)

BCP-B: Block copolymer consisting of blocks (PS) consisting of polystyrene and blocks (PMMA) consisting of poly(methyl methacrylate) (Mn: about 93,000, Mw/Mn: 1.02, composition ratio of PS/PMMA (mol %): 65/35)

BCP-C: Block copolymer consisting of blocks (PS) consisting of polystyrene and blocks (PMMA) consisting of poly(methyl methacrylate) (Mn: about 60,000, Mw/Mn: 1.02, composition ratio of PS/PMMA (mol %): 65/35)

BCP-D: Block copolymer consisting of blocks consisting of polystyrene and blocks consisting of a random copolymer of 2-hydroxy-3-(2,2,2-trifluoroethylsulfanyl) propyl methacrylate (HFMA) and methyl methacrylate (Mn: about 49,000, Mw/Mn: 1.02, composition ratio (mol %) of styrene/HFMA/methyl methacrylate: 50/1/49, prepared in accordance with example in JP 2022-20519 A).

BCP-E: Block copolymer consisting of blocks consisting of polystyrene and blocks consisting of a random copolymer of 2-hydroxy-3-(2,2,2-trifluoroethylsulfanyl) propyl methacrylate (HFMA) and methyl methacrylate (Mn: about 53,000, Mw/Mn: 1.02, composition ratio (mol %) of styrene/HFMA/methyl methacrylate: 65/1/34, prepared in accordance with example in JP 2022-20519 A).

BCP-F: Block copolymer consisting of blocks (PES) consisting of poly(4-ethylstyrene) and blocks (PMMA) consisting of poly(methyl methacrylate) (Mn: about 51000, Mw/Mn: 1.02, composition ratio of PES/PMMA (mol %): 50/50)

BCP-G: Block copolymer consisting of blocks (PES) consisting of poly(4-ethylstyrene) and blocks (PMMA) consisting of poly(methyl methacrylate) (Mn: about 55,000, Mw/Mn: 1.02, composition ratio of PES/PMMA (mol %): 65/35)

BCP-H: Mixture of a block copolymer consisting of blocks (PS) consisting of polystyrene and blocks (PMMA) consisting of poly(methyl methacrylate) (Mn: 96000, composition ratio of PS/PMMA (mol %): 65/35), a block copolymer consisting of blocks consisting of polystyrene (PS) and blocks consisting of poly(methyl methacrylate) (PMMA) (Mn; 100,000, composition ratio of PS/PMMA (mol %): 65/35), polystyrene (Mn: 2000), and poly(methyl methacrylate) (Mn: 2000) (mass ratio: 40/40/13/7).

Note that even when the same block copolymer is used, the L₀ varies slightly according to the thickness. Thus, the molecular weight was fine-tuned for BCP-A through BCP-G and the mixing ratio was fine-tuned for BCP-H such that L₀ would be constant in the examples using the same type of block copolymer. For example, BCP-A was used in Comparative Example 1 and Examples 1 to 3, but the molecular weight was varied slightly such that L₀ remained constant.

### Examples 1-1 to 1-7 and Comparative Examples 1-1 to 1-3

### Production of Structure Having Phase-separated Structure (Lamellar Structure)

A resin composition for forming a polystyrene film, which is a propylene glycol monomethyl ether acetate (PGMEA) solution of styrene/vinylbenzocyclobutene copolymer, was applied to a 12-inch silicon wafer having an antireflection film using a spinner. The coating film was baked at 250° C. for 300 seconds to form a layer consisting of a polystyrenated film on the silicon wafer. An ArF photoresist for immersion exposure was applied on the polystyrenated film to form a coating film. The formed coating film was then baked. The baked coating film was then exposed using an ArF immersion exposure machine, then post-exposure baking was performed. After development, plasma etching, subsequent resist stripping, and post-baking were used to pattern the polystyrene-enhanced film. A resin composition for forming a neutralized film, which is a PGMEA solution of styrene/methyl methacrylate/methacrylic acid hydroxyethyl copolymer, was then applied on the patterned polystyrenated film to form a coating film. The formed coating film was baked at 250° C. for 300 seconds, rinsed with OK73 thinner, and post-baked to obtain a guide substrate for evaluation with a guide pattern constituted of alternately repeating polystyrenated films and neutralized films. For the regions where alignment marks are to be formed, the polystyrenated film was formed in the region to be horizontally oriented and the neutralized film was formed in the region to be vertically oriented. PGMEA solutions of the block copolymers listed in Table 1 were applied to the guide substrates, and the coating films were baked at 90° C. for 60 seconds to form layer containing the block copolymer and having the thickness t (nm), as listed in Table 1. Phase separation pattern formation was performed by annealing at 250° C. for 30 minutes on the layer containing the block copolymer.

### Evaluation of LER (Line Edge Roughness)

From the resulting phase-separated structure, PMMA (or the copolymer block derived from methyl methacrylate) was selectively removed to form an LS pattern. SEM images of the obtained LS patterns were acquired by CD-SEM (CG6300 manufactured by Hitachi High-Tech Corporation), and the acquired SEM images were analyzed by MetroLER to determine the LER. Specifically, the line edge width (width of variation from a reference straight line) was measured at 100 locations, and the LER was calculated as three times (30) the value of standard deviation (σ) (unit: nm) obtained from the measurement results. The results are shown in Table 1.

### Evaluation of Alignment Mark Formation

SEM images (at a magnification of 10,000×) of the horizontally oriented regions of the alignment marks were acquired and observed by CD-SEM (CG6300 manufactured by Hitachi High-Tech Corporation) and evaluated according to the following criteria. The results are shown in Table 1.

Good: No extra irregularities such as an abbreviated circular shape were formed.

Poor: Extra irregularities such as an abbreviated circular shape were formed.

TABLE 1

| | | | Line | | | | |
|---|---|---|---|---|---|---|---|
| | | L₀ | dimension | Thickness t | Thickness t/ | LER | Alignment |
| | BCP | (nm) | (nm) | (nm) | L₀ | (nm) | mark |
| Comparative | A | 28.1 | 15.5 | 35 | 1.25 | 3.45 | Poor |
| Example 1-1 | | | | | | | |
| Example 1-1 | A | 28.1 | 15.5 | 42 | 1.49 | 3.37 | Good |
| Example 1-2 | A | 28.1 | 15.7 | 56 | 1.99 | 3.19 | Good |
| Example 1-3 | A | 28.1 | 15.8 | 84 | 2.99 | 2.98 | Good |
| Comparative | D | 28.5 | 16.8 | 35 | 1.23 | 3.41 | Poor |
| Example 1-2 | | | | | | | |
| Example 1-4 | D | 28.5 | 16.8 | 43 | 1.51 | 3.34 | Good |
| Example 1-5 | D | 28.5 | 17.0 | 57 | 2.00 | 3.18 | Good |
| Comparative | E | 28.0 | 15.4 | 35 | 1.25 | 3.39 | Poor |
| Example 1-3 | | | | | | | |
| Example 1-6 | F | 28.0 | 15.4 | 42 | 1.50 | 3.31 | Good |
| Example 1-7 | F | 28.0 | 15.6 | 56 | 2.00 | 3.17 | Good |

Table 1 shows that the line roughness can be improved and alignment marks can be formed well by setting the thickness t of the layer containing the block copolymer such that the relationship between the thickness t and the block copolymer period L₀ satisfies a specific formula.

### Examples 2-1 to 2-10 and Comparative Examples 2-1 to 2-6

### Production of Structure Having Phase-separated Structure (Cylinder Structure)

On a 12-inch silicon wafer having a SOC (Spin on Carbon) film and a SOG (Spin on Glass) film on the SOC film as an anti-reflective film, a resin for forming a thermally cross-linking neutralized film, which is a PGMEA solution of styrene/methyl methacrylate/methacrylic acid hydroxyethyl copolymer, was applied using a spinner. A neutralized film was formed on the silicon wafer by baking the coated film at 240° C. for 60 seconds. An ArF photoresist for immersion exposure was applied to the neutralized film to form a coating film. The formed coating film was then baked. The baked coating film was then exposed using an ArF immersion exposure machine, and then post-exposure baking was performed. After development, plasma etching, subsequent resist stripping, and post-baking were used to pattern the neutralized film. A resin composition for forming a polystyrenated film, which is a propylene glycol monomethyl ether acetate (PGMEA) solution of styrene/methacrylic acid hydroxyethyl copolymer, was then applied on the patterned neutralized film to form a coating film. The formed coating film was baked at 200° C. for 120 seconds, rinsed with OK73 thinner, and post-baked to obtain a guide substrate for evaluation with a circular polystyrenated film aligned in a plan view at a position corresponding to the hexagonal densest structure and a neutralized film formed in between. For the regions where alignment marks are to be formed, the polystyrenated film was formed in the region to be horizontally oriented and the neutralized film was formed in the region to be vertically oriented. PGMEA solutions of the block copolymers listed in Table 1 were applied to the guide substrates, and the coating films were baked at 90° C. for 60 seconds to form layers containing the block copolymer and having the thickness t (nm), as listed in Table 1. Phase separation pattern formation was performed by annealing at 250° C. for 30 minutes on the layer containing the block copolymer. In Comparative Examples 2 and 3, misalignment was not evaluated because pattern formation was not possible.

### Evaluation of Misalignmen

From the resulting phase-separated structure, PMMA (or a copolymer block derived from methyl methacrylate) was selectively removed to form a CH pattern. SEM images of the obtained CH patterns were acquired by CD-SEM (CG6300 manufactured by Hitachi High-Tech Corporation), and the acquired SEM images were analyzed by MetroLER to determine misalignment. Specifically, the distance between the centers of gravity of holes was measured at 5,000 locations, and the misalignment was calculated as three times (36) the value of standard deviation (σ) (unit: nm) obtained from the measurement results. The results are shown in Tables 2 and 3.

### Evaluation of Alignment Mark Formation

SEM images of the horizontally oriented regions of the alignment marks were acquired and observed by CD-SEM (CG6300 manufactured by Hitachi High-Tech Corporation) and evaluated according to the following criteria. The results are shown in Tables 2 and 3.

Good: No extra irregularities such as an abbreviated circular shape were formed.

Poor: Extra irregularities such as an abbreviated circular shape were formed.

TABLE 2

| | | | Hole | | | | |
|---|---|---|---|---|---|---|---|
| | | L₀ | diameter | Thickness t | Thickness t/ | Misalignment | Alignment |
| | BCP | (nm) | (nm) | (nm) | L₀ | (nm) | mark |
| Comparative | B | 40.0 | 18.1 | 53 | 1.33 | 3.87 | Poor |
| Example 2-1 | | | | | | | |
| Example 2-1 | B | 40.0 | 17.8 | 80 | 2.00 | 3.15 | Good |
| Example 2-2 | B | 40.0 | 17.3 | 110 | 2.75 | 2.85 | Good |
| Comparative | C | 30.1 | 12.2 | 42 | 1.40 | 3.66 | Poor |
| Example 2-2 | | | | | | | |
| Comparative | C | 30.1 | — | 50 | 1.66 | — | Poor |
| Example 2-3 | | | | | | | |
| Example 2-3 | C | 30.1 | 11.5 | 64 | 2.13 | 3.36 | Good |
| Example 2-4 | C | 30.1 | 11.2 | 88 | 2.92 | 3.26 | Good |
| Comparative | E | 30.0 | 12.2 | 42 | 1.40 | 3.68 | Poor |
| Example 2-4 | | | | | | | |
| Example 2-5 | E | 30.0 | 11.7 | 64 | 2.13 | 3.35 | Good |
| Example 2-6 | E | 30.0 | 11.3 | 88 | 2.93 | 3.23 | Good |
| Comparative | G | 30.1 | 12.1 | 42 | 1.40 | 3.70 | Poor |
| Example 2-5 | | | | | | | |
| Example 2-7 | G | 30.1 | 11.6 | 64 | 2.13 | 3.39 | Good |
| Example 2-8 | G | 30.1 | 11.2 | 88 | 2.93 | 3.27 | Good |

TABLE 3

| | | | Hole | | | | |
|---|---|---|---|---|---|---|---|
| | | L₀ | diameter | Thickness t | Thickness t/ | Misalignment | Alignment |
| | BCP | (nm) | (nm) | (nm) | L₀ | (nm) | mark |
| Comparative | H | 40.0 | 17.9 | 53 | 1.33 | 3.95 | Poor |
| Example 2-6 | | | | | | | |
| Example 2-9 | H | 40.0 | 17.5 | 80 | 2.00 | 3.22 | Good |
| Example 2-10 | H | 40.0 | 17.0 | 110 | 2.75 | 2.90 | Good |

Tables 2 and 3 show that setting the thickness t of the layer containing the block copolymer such that the relationship between the thickness t and the block copolymer period L₀ satisfies a specific formula can improve misalignment of the cylinder structure and allow alignment marks to be formed well.

What is claimed is:

1. A method for producing a structure having a phase-separated structure, the method comprising:
forming a layer including a block polymer and having a thickness t (nm) on a substrate using a resin composition containing the block polymer; and
phase separating the layer into a cylinder structure,
wherein the thickness t is set such that a relationship between the thickness t and a period L₀ (nm) of the block copolymer satisfies (2L₀+(3^{0.5}/2) L₀×n)×0.9≤t≤(2L₀+(3^{0.5}/2) L₀×n)×1.1, wherein n is an integer between 0 and 3 inclusive.

2. The method according to claim 1, wherein n is an integer between 1 and 3 inclusive.

3. A method for improving misalignment of a cylinder structure and alignment mark formation, the method comprising:
forming a layer including a block copolymer and having a thickness t (nm) on a substrate using a resin composition containing the block copolymer; and
phase separating the layer into a cylinder structure,
wherein the thickness t is set such that a relationship between the thickness t and period L₀ (nm) of the block copolymer satisfies (2L₀+(3^{0.5}/2) L₀×n)×0.9≤t≤(2L₀+(3^{0.5}/2) L₀×n)×1.1, wherein n is an integer between 0 and 3 inclusive.

4. A method for producing a structure having a phase-separated structure, the method comprising:
forming a layer including a block copolymer and having a thickness t (nm) on a substrate using a resin composition containing the block copolymer; and
phase separating the layer into a lamellar structure,
wherein the thickness t is set such that a relationship between the thickness t and a period L₀ (nm) of the block copolymer satisfies (1.5L₀+0.5L₀×m)×0.95≤t≤(1.5L₀+0.5L₀×m)×1.05, wherein m is an integer between 0 and 5 inclusive.

5. The method according to claim 4, wherein m is an integer between 1 and 5 inclusive.

6. A method for improving line roughness and alignment mark formation, the method comprising:
forming a layer including a block copolymer and having a thickness t (nm) on a substrate using a resin composition containing the block copolymer; and
of phase separating the layer into a lamellar structure,
wherein the thickness t is set such that a relationship between the thickness t and a period L₀ (nm) of the block copolymer satisfies (1.5L₀+0.5L₀×m)×0.95≤t≤(1.5L₀+0.5L₀×m)×1.05 (b, wherein m is an integer between 0 and 5 inclusive.
